(19) United States
(12) Patent Application Publication
(10) Pub. No.: US 2008/0264784 A1
(43) Pub. Date: Oct. 30, 2008

(54) Media Injector

(76) Inventors: Peter Pecher, Augsburg (DE); Eckhard Wirth, Gelnhausen (DE); Roland Schneider, Hanau (DE)

Correspondence Address: CANTOR COLBURN, LLP, 20 Church Street, 22nd Floor, Hartford, CT, 06103, US

(21) Appl. No.: 11/628,525

(22) PCT Filed: Jun. 2, 2005
(86) PCT No.: PCT/EP2005/005949

§ 371 Date: Mar. 3, 2008

(30) Foreign Application Priority Data
Jun. 18, 2004 (DE) 10 2004 029 466.6

(51) Int. Cl. C23C 14/34

(52) U.S. Cl. 204/298.07

(57) ABSTRACT

The invention relates to a media injector for transporting a particularly fluid medium into a processing chamber, preferably consisting of a supply device and at least one gap acting as a transport opening for the medium, wherein said gap comprises at least two gap defining surfaces with a gap arranged therebetween. According to the invention, at least one gap defining surface is defined by at least one part of at least one front surface of a first tubular element.

The invention relates to a media injector according to the preamble of Claim 1 and a plasma source and sputtering device according to the preambles of Claim 27 and 35.

A generic media injector is used to transport a fluid medium, preferably a gas, a liquid, vapors or solutions, suspensions, emulsions, colloids, pastes, smoke or the like into a processing chamber, preferably in conjunction with technical utilization of plasmas, and is already known in different variants, only some of which are mentioned below. A gas nozzle is known from DE 39 351 89 A1, with which the process gas mixture can be admitted through a number of openings into a reaction chamber of an apparatus for treatment of work pieces by reactive ion etching. A sputtering device for coating of substances is known from DE 43 011 89 C2 with two electrodes and a shield for the electrodes. A substrate support can be moved parallel to the surface of the two electrodes. A gas line, through which process gases are introduced to the plasma chamber of the apparatus, is arranged in the dark space shield and beneath the surface of one of the electrodes. In order to counteract entrainment of plasma and the formation of parasitic plasmas, the distance from the electrode to the dark space shield is less than the dark space distance. A magnetron sputtering electrode with an anode and cathode shield is known from U.S. Pat. No. 6,171,461 B1. The cathode shield is enclosed by the anode shield. Process gas is introduced via a gas inlet in the area between the anode shield and the cathode shield, which can flow over the surface of the sputtering target.

A device for reactive coating of substrates according to the magnetron principle is described in WO 96/26533, whose target consists of at least two galvanically separated partial targets. The partial targets are concentrically arranged and form a so-called two-ring source. Annular intermediate pieces are arranged concentrically in the center of the internal partial target and between the partial targets. A channel is introduced into the intermediate pieces, into which reaction gas is supplied via lines. This emerges from nozzles distributed around the periphery, so that it propagates over the partial targets. A film formation chamber of a film formation device is described in DE 199 4 039 A1, in which a mixed gas, comprising a sputtering gas and a reactive gas, is fed to the film formation chamber through a gas inlet opening. A microwave plasma burner with a coaxially designed gas feed is known from EP 0 296 921 B1. A coating device for substrates is shown in EP 0 463 230 B1, in which a device for generation of a plasma cloud is provided, which has an electron emitter with a tubular anode connected afterward. The anode is provided with an inlet for the process, which is designed as a gas nozzle. For use in a reactor to treat a surface of a substrate, a reactor with a nozzle head is proposed in EP 0 709 486 B1, which has a planar arrangement of openings arranged at limited spacing, through which a gas can be sprayed into the treatment chamber of the reactor for deposition on the wafer. US 2002/0096258 A1 also describes a plasma reactor, which exhibits isotropic etching of a substrate with a centrally arranged gas inlet to achieve the most uniform possible plasma potential.

It is already known from DE-OS 2 149 606 and US 2002/0108571 A1 to provide a gas inlet in the interior of a shield. A glow discharge apparatus for deposition of semiconductor layers with a cathode and a cathode shield is also disclosed in U.S. Pat. No. 4,574,733. A process gas can be introduced into the region of the cathode by means of a process gas feed with gas nozzles. A gas line provided with holes to supply gas to a plasma reactor is already known from U.S. Pat. No. 5,811,022, which surrounds a semiconductor wafer being processed. A perforated shield is known from U.S. Pat. No. 6,296,747 B1 to produce a sputtering reactor with a gas inlet with high conduction value, which contains a number of holes, through which the process gas can flow. For improvement of plasma distribution in an inductively coupled plasma, it is proposed in WO 02/19364 to use shields with slits and holes for gas inlet and gas distribution in a process chamber.

A device for uniform distribution of a gas concentration within a process chamber with a porous ceramic tube is described in WO 95/620652. A gas injection system for injection of one or more process gases into a reaction chamber is disclosed in EP 0 823 491 B1 with one or more slits and holes in one part of the bottom surface in a side wall.

The task of the present invention is to devise a media injector for transport of an especially fluid medium into a processing chamber, which has a simple and, at the same time, stable design and can be implemented cost-effectively. Another task is to devise a plasma and/or ion device, for example, a plasma, ion or sputtering source, with a media inlet device designed as a media injector, which has a simple and, at the same time, stable design and is cost-effective to implement.

The mentioned tasks are solved according to the invention with the features of the independent patent claims. Modifications can be deduced from the dependent claims.

A media injector according to the invention for transport of an especially fluid medium into a processing chamber preferably contains at least one feed device and at least one gap as transport opening for the medium. The gap has at least two gap limitation surfaces with a gap space arranged in between, at least one gap limitation surface being formed by at least part of at least one face of a first tubular element.

The invention starts from the finding that tubular parts, whose faces form a gap limitation surface, have high stability and can be produced cost-effectively with high accuracy, for example, by turning. The media injector according to the invention also permits more uniform gas distribution, than, say, holes, nozzles or openings by creating a high-precision gap as transport opening. A spatial area, in which a medium can be transported through the gap, regardless of whether additional physical or chemical processes occur, is referred to as processing chamber according to the invention.

In a generic media injector, in addition to its design, additional parameters, like the distribution of medium in the feed and processing chamber to be achieved with it, its positioning in the processing chamber, as well as its mechanical, thermal and chemical stability relative to the medium, are significant. A generic media injector can be used, in order to obtain layered flow distributions without chemical or physical reactions. When a generic media injector is used in the field of plasma technology, the effect of parameters, like ion flow, formation of activated species, arcing and dark spaces, as well as pressure and potential distributions in the plasma, must be allowed for by appropriately configuring the media injector. During use in plasmas, it is advantageous if it has sufficient plasma resistance with a view toward longer lifetime of the media injector.

The media injector is preferably designed as a gas nozzle in gaseous media.

The preferably provided feed device can expediently be designed as a feed line. In another variant, an internal processing chamber can be arranged in a supply chamber of the medium and the medium can flow into the processing chamber through the media injector.

When the media injector is designed so that a second gap limitation surface opposite the first gap limitation surface is formed by at least part of one face of a second tubular element, the gap space can be cost-effectively dimensioned with high accuracy by simple positioning of the faces of the first and second tubular element.

In a modification of the invention, however, the second gap limitation surface opposite the first gap limitation surface can be formed by a surface of a non-tubular work piece, so that a combination of gap limitation surfaces is achieved with available components that are integrated into an overall function.

In another variant of the media injector, the gap is part of an electrode arrangement, through which a media inlet becomes possible near an area, in which the electric and/or magnetic fields are active in the processing chamber.

A conductor, preferably a metal, especially steel, stainless steel, titanium, aluminum, copper, tantalum, tungsten, molybdenum, graphite, a semiconductor or insulator, preferably made of ceramic or plastic, is expediently provided as material for elements, components or work pieces. It is then understood that both different and individual elements can consist of different materials.

If a media injector according to the invention is prescribed to supply the medium into a processing chamber of a plasma device, a stable process-optimized feed of the medium can be achieved with it. A gap, which is assigned to a Faraday dark space of the plasma, which can be used as an area for introduction of the medium, is advantageous. The Faraday dark space is not intended for active isolation between adjacent components, but necessary, so that no parasitic plasma can ignite between two components with at least temporarily different potential, which then generally produces a conducting connection.

A plasma and/or ion device according to the invention has a media injector according to the invention.

A plasma source with at least one gas inlet device for ionizable gas to generate a plasma and at least one cathode for generation of electrons for ionization of the gas, as well as at least one anode allocated to the cathode, is preferred. At least one gas inlet device is designed as a media injector according to the invention. It is understood that the media injector can also be used in plasma sources without electrodes and in plasma sources with one or more electrodes without electron emitter (for example, inductively coupled sources).

This type of plasma source therefore has a gas inlet device that can be operated with high stability and produced cost-effectively.

A sputtering device according to the invention for coating of substrates has at least one gas inlet device for the sputtering and/or reactive gas and a sputtering cathode, which includes at least one sputtering target with a sputtering surface. At least one gas inlet device is designed as a media injector according to the invention.

Precise and cost-effective influencing of the operating and processing parameters is possible in a plasma source or sputtering device according to the invention via the media injector design according to the invention.

Additional variants, advantages and aspects of the invention are explained below, independently of their summary in the patent claims, schematically with reference to the drawings, without restriction of generality.

In the drawings:

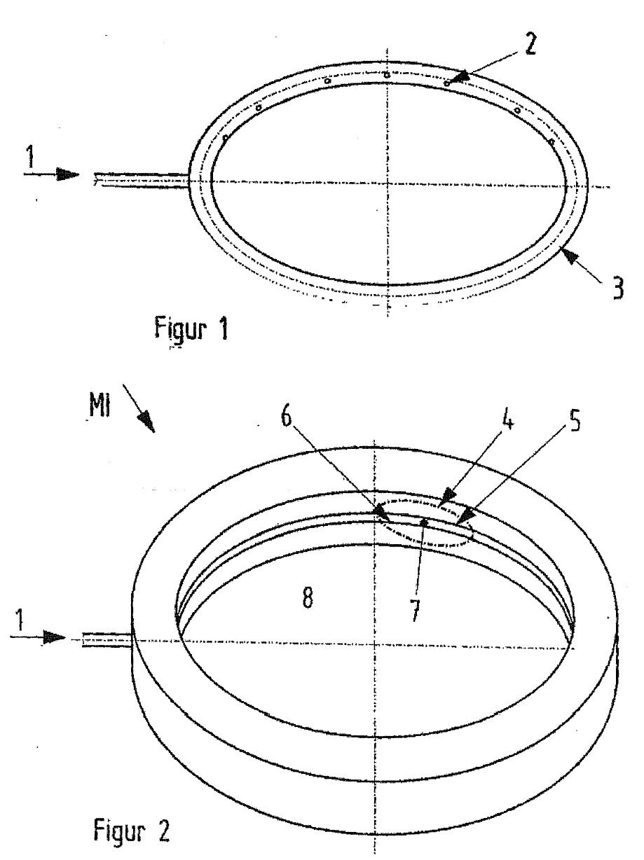

FIG. 1 shows an annular nozzle known from the prior art

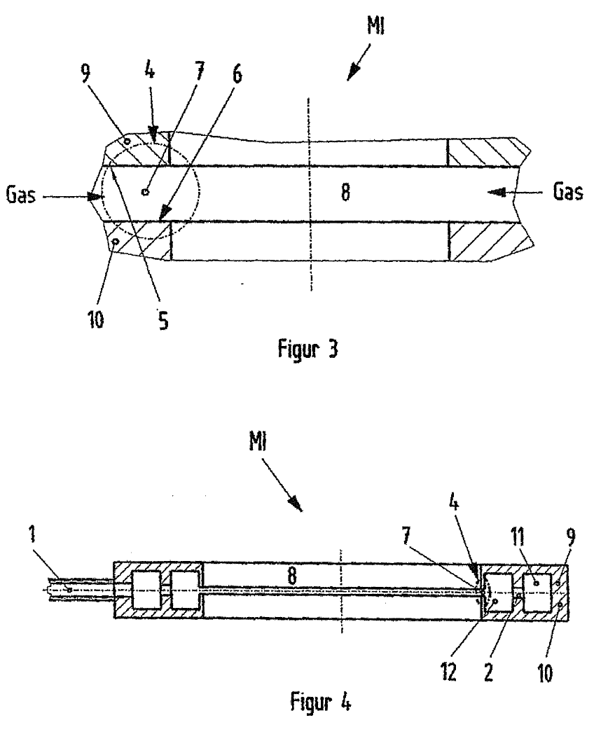

FIG. 2 shows a media injector

FIG. 3 shows the gap configuration in a media injector

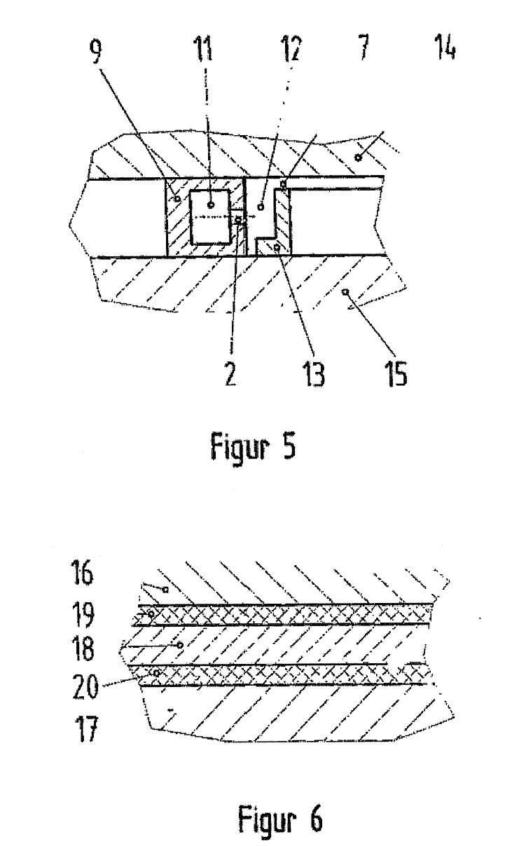

FIG. 4 shows a sectional view of a media injector with a supply space

FIG. 5 shows a media injector with an overflow

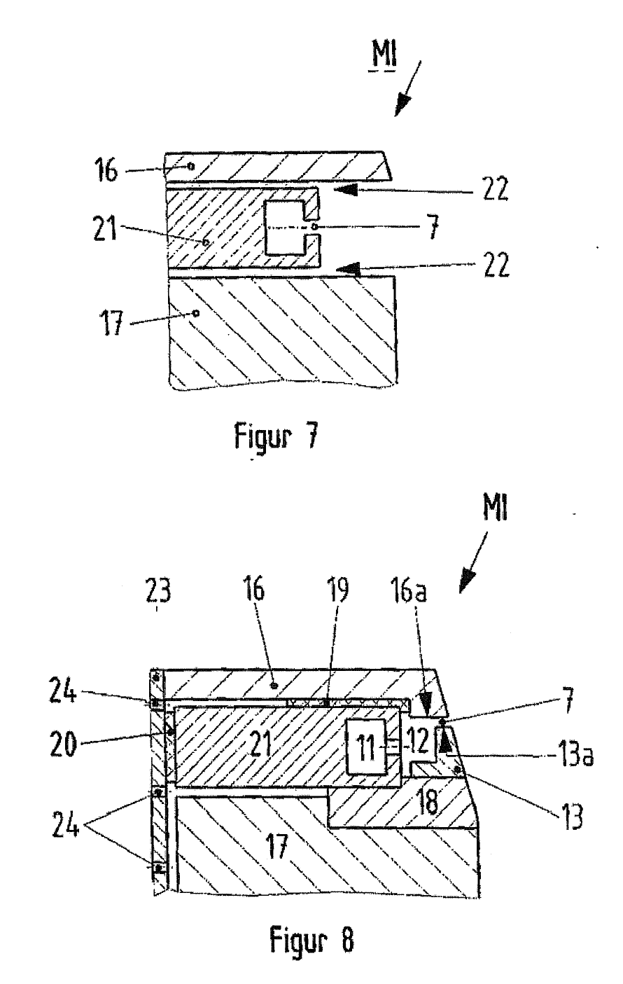

FIG. 6 shows a configuration of a gap space filled with work pieces

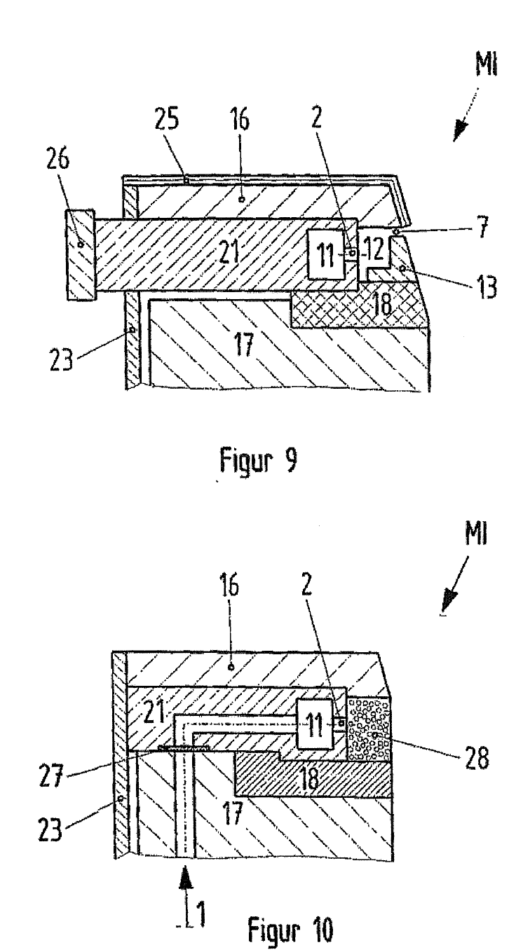

FIG. 7 shows a media injector with a gas nozzle arranged between two electrodes

FIG. 8 shows a media injector preferably for a plasma source

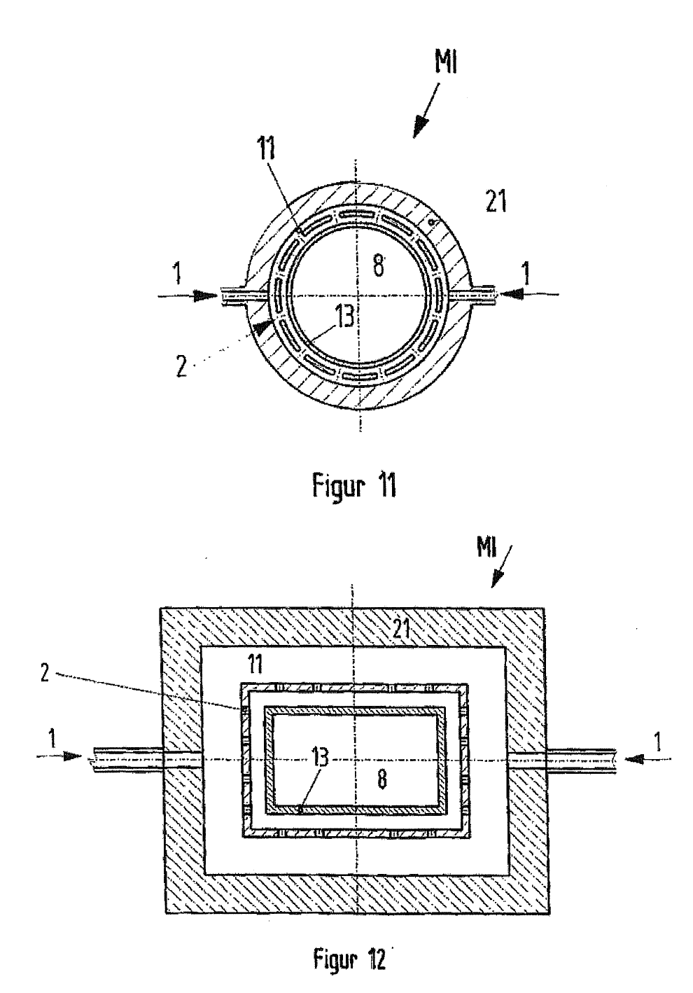

FIG. 9 shows a modification of the variant of FIG. 8

FIG. 10 shows another variant of a media injector, preferably for a plasma source

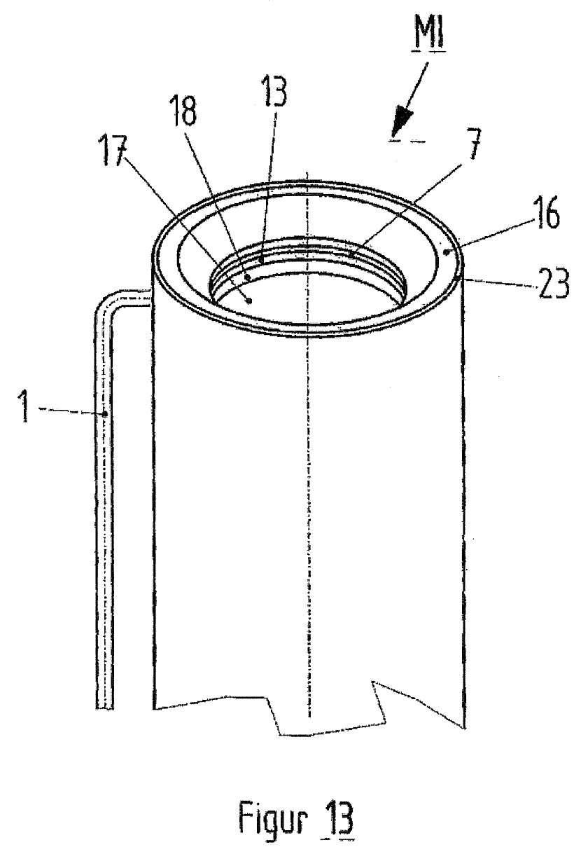

FIG. 11 shows a horizontal section through an essentially rotationally symmetric media injector

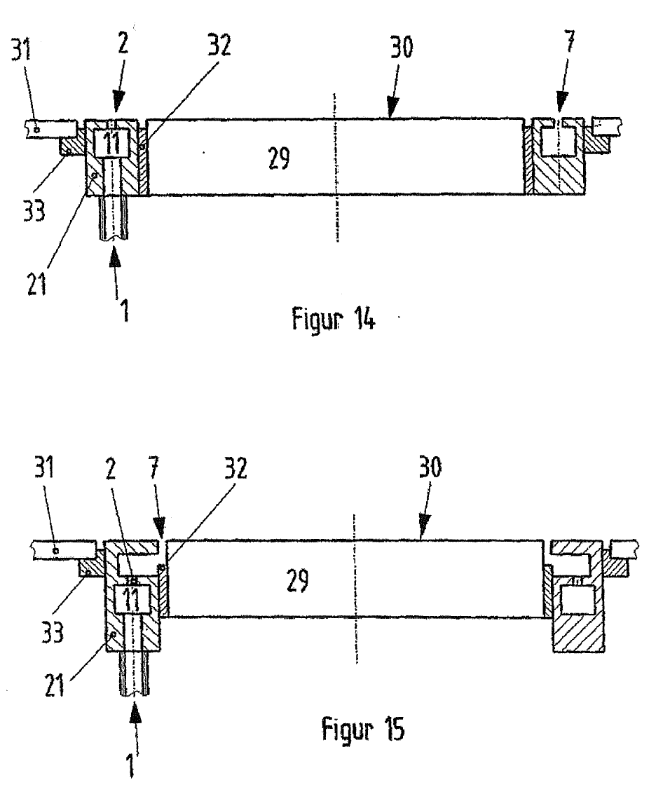

FIG. 12 shows a horizontal section through a rectangular plasma source

FIG. 13 shows a spatial view of a rotationally symmetric plasma source with media injector

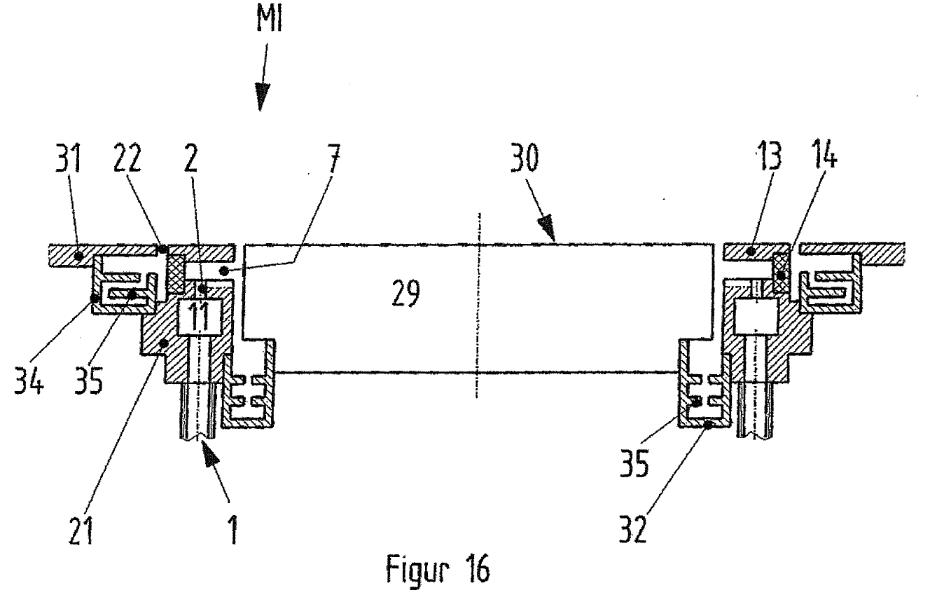

FIG. 14-17 each show a vertical section through a sputtering device with media injector

The same reference numbers are used below for the same components in the different figures. A media injector for gas feed into an enclosed spatial area, designed as an annular nozzle known from the prior art, is shown in FIG. 1, which consists of an essentially annular gas line 3 with a gas feed 1 and several outlet openings 2, like holes or the like, through which the gas can emerge from the gas line. This type of annular nozzle is used, for example, in a plasma source to supply oxygen into a circular area above the outlet opening of the plasma. Direct feed of oxygen into the interior of the source is not possible with the known annular nozzle. Feed through the holes 2 also causes spatial non-homogeneities of the supplied gas, which can have an adverse effect on different operating parameters of the plasma source, like ion current density or arcing probability.

FIG. 2 shows a view of components of media injector according to the invention with a gas feed line 1 and a gap 4 as transport opening for the medium. The gap 4 has two gap limitation surfaces 5, 6 with a gap space 7 arranged in between, the latter being specially connected to a processing chamber 8.

As shown more precisely in a section in FIG. 3, the gap limitation surfaces 5, 6 are each formed by part of a face of two tubular components (tubular elements) 9 and 10. The faces or gap limitation surfaces 5, 6 can have any angle to the axis of the tubular element. Gas feed, in the case of FIG. 3, occurs from the outside into gap space 7. The media injector MI, according to FIG. 3, can be designed linear or as a curved component. A more uniform gas distribution can be achieved in processing chamber 8 in comparison with gas amounts introduced with nozzles or holes. In the variant of FIG. 2, the gap precisely encloses the processing chamber 8. It is understood that the invention also includes configurations of the gap, in which a processing chamber is partially enclosed or enclosed several times by the gap.

Relative to a slotted tube, the media injector according to the invention has higher stability, especially long-term and process stability, since possible spacing changes of the gap limitation surfaces caused by external mechanical forces or heat expansion forces can be reduced. The distance between the gap limitation surfaces can be precisely defined by simple spacers and stabilized relative to external effects.

The new media injector MI can be combined with a conventional gas nozzle with outlet openings, like holes, nozzles, slits or perforations, in order to achieve modulated or more uniform distribution of the gas, as illustrated in FIG. 4. The gas flowing through gas feed line 1 traverses a conventional gas nozzle with a gas channel 11 and with holes 2 for gas outlet and enters the gap space 7 via an additional gas channel 12. The gas channels 11 and 12 are preferably formed here like the gap space 7 of tubular elements 9 and 10. The gas channel 12, at the same time, forms a supply space for gap 4, through which pressure fluctuations of the gas can be buffered. By combining the gap 4 of the media injector MI according to the invention with the holes or openings of the conventional gas nozzle, spatial modulation or equalization of the gas distribution in processing chamber 8 can be achieved. In addition, by combining holes or openings with a gap configuration, a situation can be achieved in which a stipulated gas distribution is also guaranteed in a gap having higher manufacturing tolerances.

In one modification of the invention, a number of gap segments are formed between the tubular elements. The media injector according to the invention can be designed, so that a second gap limitation surface opposite the first gap limitation surface is formed by a surface of a non-tubular work piece. This surface is preferably flat. A variant is shown in FIG. 5, in which, as in FIG. 4, a conventional gas nozzle with holes 2 and a gas channel 11 permits transport of the gas into a supply space 12, which is connected to gap space 7. The gas channel 11 is formed here by a tubular element 9. The gap space 7 is situated between the face of a gas nozzle ring 13 designed as a tubular element and an arbitrary non-tubular work piece 14. Since the gap space 7 is arranged in the upper end area of the gas nozzle ring 13, the media injector is designed here as an overflow. The gas nozzle ring 13 itself is arranged between two non-tubular work pieces 14 and 15.

Instead of the two-part variant of FIG. 5, a one-part variant similar to FIG. 4 can be chosen.

The invention also includes variants, in which several faces of the tubular elements are provided to form a structured gap space, and/or in which a gap has more than two gap segments. The tubular element can have a cross-section with a closed periphery to form a continuous gap. It is preferred, if the tubular element has a circular, oval, polygonal or rectangular cross-section. It is understood that the cross-section can also quite generally consist of curved sections with different radii connected singly or in multiple fashion.

The media injector according to the invention is advantageously used for transport of a preferably fluid medium into a processing chamber in any apparatus. Examples of this are gas washers, fermenters and mixing reactors. However, use in apparatus in which a plasma is generated and/or used is particularly preferred. The media injector is preferably designed, so that the gap is part of an electrode arrangement. It is therefore possible to introduce the medium into an area, in which particularly adapted conditions for making the medium effective are present. Additional available elements can also optionally be used to form the gap. In one modification of the invention, at least parts of the gap limitation surface lie at least temporarily at different electric potentials.

The media injector according to the invention can advantageously be configured to prevent arcing between two electrodes that have, at least temporarily, different potentials. As is known per se, arcing between two electrodes with different potentials can be prevented, if the intermediate space between the two electrodes is reduced or the plasma pressure in between is reduced. The pressure between the electrodes can be reduced by pumping or, if a higher pressure prevails between the electrodes than spatially behind one of the electrodes, by arranging holes in the last-named electrode. Such holes need only be dimensioned large enough, so that the corresponding function of the electrode is not compromised. For example, the function of the electrode as a shield must also be guaranteed when holes are present. Holes are also preferably made in the electrode in an area that is less critical with respect to arcing, and/or in which the pressure is sufficiently low on the side of the electrode facing away from the intermediate space of the two electrodes. To prevent arcing between two electrodes, an intermediate space between the electrodes can also be filled at least partially with an appropriate material.

In FIG. 6, two electrodes 16 and 17 form a gap with work pieces 18, 19, 20 arranged in between them. The electrodes 16, 17 and the work pieces 18, 19, 20 can optionally consist of conductors, semiconductors or insulators, or also be made from different materials. For example, a work piece 18, 19, 20 made of metal can be coated with a ceramic or a plastic, in order to combine good insulating effect with good heat conductivity. The intermediate space between the electrodes 16, 17 can also be partially filled with one or more work pieces, which at least partially touch at least one of the electrodes 16, 17. The area between the electrodes 16 and 17 can also be completely filled by the work piece 18. The work pieces 18, 19, 20 that fill the area between the electrodes 16, 17 can lie at different potential. The work pieces 18, 19, 20, in particular, can lie at the potential of one of the electrodes, at any intrinsic potential applied from the outside or at the ground potential of the surroundings. The work pieces can also lie at a floating potential, i.e., be insulated, so that a potential value is dynamically adjusted.

Since the function of an injector is favorably influenced, especially when the media injector is used in the field of plasma technology, by exact maintenance of specific geometric specifications, reliable positioning of the injector, as well as its components, is advantageous. Positioning of at least one element, component and/or work piece of the media injector by shape-mated fastening is therefore preferably prescribed. Rotationally symmetric parts can be joined in shape-mated fashion with particular simplicity by providing so-called centerings on the parts being joined. The gap 4 can preferably be formed by two spaced circular rings, stacked one above the other, which are preferably provided with centerings. A modification in which the circular rings are designed one in the other for centering or self-centering is particularly preferred.

Centering can also be produced by one or more work pieces arranged between the electrodes 16, 17, which at least partially fill-up the intermediate space between the electrodes. A work piece or several work pieces can also be adapted, so that they fulfill more than one function. It is preferably prescribed that the two electrodes be insulated by one or more work pieces and good heat transport additionally guaranteed between the electrodes. The work piece or work pieces can consist of insulating material. In another variant, several materials are combined. In another modification, a material with good heat conduction, which is also electrically conducting, for example, a metal, like silver, copper or aluminum, is combined with one or more layers of insulators that are preferably made thin with poor heat conduction. A configuration, in which an electrode is actively or passively cooled and absorbs heat, among other things that develops on the other electrode, is preferred.

In a preferred variant of the invention, a Faraday dark space of the plasma is allocated to the gap. Gas inlet preferably occurs into the Faraday dark space between two electrodes. As a result of transport of the medium, an area of increased pressure develops in the gap space in contrast to the desired pressure reduction described from the prior art to reduce arcing. In the media injector according to the invention, it was found that gas feed into the gap space between two electrodes can surprisingly occur without arcing. The electrodes can then lie at any potential. It is understood that one of the electrodes can also lie at ground potential.

When a media injector according to the invention is used for a plasma source, the ion current density can be significantly increased and the probability of arcing reduced. Optimized distribution of ion current density and activated reactive species, like activated oxygen, is also made possible.

The media injector according to the invention is preferably used in a plasma source known from EP 0 463 203 A1. The content of this document is therefore fully included for characterization of the aspects of the present invention. The plasma source has an electron emitter with a tubular anode connected after it and is provided with an inlet for process gas for emission of the plasma. The plasma source is also equipped with magnets for alignment and guiding of the plasma through the anode tube into the processing chamber. A device for generation of atoms, molecules or clusters of materials to produce a layer on the substrates is arranged in the processing chamber. This is preferably an electron beam evaporator, a thermal evaporator or a sputtering cathode. The plasma source is also provided with a dark space shield, which ensures that undesired additional plasmas are prevented. In the known device for coating of substrates or the plasma source used in them, supply of gas occurs through inlet connectors with correspondingly non-homogeneous distribution of gas in the feed space. A plasma source of this type is known from EP 1 154 459 A2, in which feed of reactive gas occurs through a gas ring above the plasma source. Feed of gas according to the invention occurs in such plasma sources through at least one media injector according to the invention.

A media injector MI according to the invention for a plasma source with a gas nozzle 21 arranged between two electrodes 16, 17 is shown in FIG. 7. If the gas nozzle 21 has a gap, the configuration of FIG. 7 represents two media injectors according to the invention lying one within the other. The gas nozzle 21 can also be designed as conventional gas nozzles with holes, openings or nozzles, or represent a combination of the two. The gap 22 between gas nozzle 21 and electrodes 16, 17 can be partially or fully filled with material. In a modification of this variant, the gas nozzle 21 can be integrated in one of the electrodes 16, 17. The intermediate space between the electrodes 16, 17 can also be filled totally or partially with material, for example, an insulator. The depiction in FIG. 7 is preferably supplemented by a corresponding mirror-image second configuration, especially in an injector with a circular cross-section or another at least partially closed cross-sectional shape.

The variant of the invention depicted in FIG. 8 shows a configuration particularly preferred for plasma sources, in which a plasma burns in an area in front of electrodes 16, 17. The electrodes 16, 17 need not necessarily be the driving electrodes (cathode, anode, HF electrode, etc.) of the plasma. This variant is preferably part of an injector with circular cross-section. The intermediate space between electrodes 16, 17 is filled with several filling components 13, 18, 19, 21. A gas nozzle ring 13 is mounted in front of the gas nozzle 21, whose face 13a forms a first gap limitation surface, whereas the second gap limitation surface is formed by the face 16a of electrode 16, when these components are designed as tubular elements. The space between the gas nozzle ring 13 and the gas nozzle 21, on the one hand, and the electrode 17, on the other, can be at least partially filled with work piece 18. A work piece 19 can be provided between the gas nozzle 21 and the electrode 16. To influence the electric fields in the region of the media injector MI, an additional electrode 23 is provided, which can lie at the same potential or a different potential as electrodes 16 or 17. The electrode 16 preferably lies at ground potential and forms a shield relative to external fields, when the electrode 16 defines the outlet opening of the source. Depending on the material used for work piece 19, the gas nozzle 21 can lie at the same or different potential as electrode 16. When the work piece 18 is designed as an insulator, a floating potential is obtained for the gas nozzle ring 13. The gap space 7 is preferably a Faraday dark space, through which gas coming from gas channel 11 can be injected into the burning plasma. The electrode 23 can have holes 24 that can be used for venting the enclosed cavities. A work piece 20 can also be provided, which insulates the electrode 23 from electrode 17 and/or gas nozzle 21. It is understood that variants of the media injector, in which components shown in FIG. 8, especially work pieces 18, 19, 20 and/or holes 24 are missing, are also included by the invention. The electrode 16 can also preferably lie at a potential other than ground potential in a plasma source with several electrodes. The components 7, 13 and 16 of the media injector according to the invention form a sloped surface, so that a concave outlet opening from the plasma can be created.

The variant of the new media injector in FIG. 8 can be configured, so that the individual parts are firmly fastened to each other, preferably by geometric shaping, in which the parts match each other and/or by other fastening with machine elements, for example, bushings, screws, pins and the like. If necessary, the corresponding machine elements are made from non-conducting material, like ceramic or plastic. Each component can also be actively or passively cooled, for example, by a medium or by heat conduction or heat radiation. Each component can be produced from a material that is at least partially coated with at least one other material. Work piece 18 preferably consists of ceramic or copper, which was coated with ceramic, if increased heat removal in a cooled electrode 17 is provided. In another variant, the work piece 18 can be designed as a magnetic yoke ring. The gas nozzle ring 13 preferably consists of a plasma-stable material, for example, titanium, tantalum, tungsten, molybdenum, carbon, niobium or ceramic. The electrode 17 preferably consists of a material with higher heat conductivity to remove heat forming on other components, for example, on the electrode 16 or gas nozzle 21. For this purpose, it is prescribed that good heat contact is produced between the electrode 17 and the parts and components, on which heat develops. The electrode 17 is preferably actively or passively cooled. During passive cooling, a design of the electrode 17 from a material with good heat conductivity, for example, silver, copper, aluminum, and with a large cross-section and an appropriate coating is particularly preferred. A material with high emissivity for heat radiation or an electrical insulating effect is favorable. The electrode 23 can be coated black, especially anodized, like the other components.

In a preferred variant of FIG. 8 fixed fastening of the electrodes 16, 23 guarantees reliable electrical contact, as well as high mechanical stability. The stable geometry prevents short circuits between electrodes 16 and 23 and the electrodes or work pieces lying at different potential, like electrode 17. The mechanical and geometric stability of the complex arrangement is achieved, especially in that all work pieces connected to each other are fastened and/or screwed or connected by pins in shape-mated fashion by means of centerings.

Another embodiment of the variant in FIG. 8 is shown in FIG. 9, in which different equivalent parts of FIG. 8 are not show, for better clarity, but which could be used accordingly. The electrode 16 in FIG. 9 is additionally provided at least partially with a plasma shield 25. The plasma shield advantageously consists of a plasma-stable material, like tantalum, titanium, niobium, molybdenum, tungsten, carbon or ceramic (for example, aluminum oxide, boron nitrite, etc.), and can be releasably fastened to electrode 16. A cooling element 26 is mounted on the gas nozzle 21 for cooling, which is actively cooled or can be designed as a passive cold surface. The cold surface can be connected to an active cooling loop or cooling by heat transport, preferably using at least one phase transition. If the cooling element is cooled with at least one medium, it is advantageous to configure the lines of the medium or media at least partially flexible. Each component of the media injector can also be actively or passively cooled. Cooling of the electrodes and/or gas nozzle is preferably provided. Cooling by a cold surface, for example, a screwed-on part, which is traversed by water, preferably occurs.

A modification of the media injector according to the invention is shown in FIG. 10, in which a gas feed line 1 is guided through an electrode 17 to a gas nozzle 21. When the electrode 17 and gas nozzle 21 lie at different potentials, the gas feed line 1 can be insulated from electrode 17 and/or an insulator or semiconductor provided between the parts having different potentials.

To suppress parasitic plasmas, gratings 27 or porous work pieces can be inserted into gas feed 1, which can consist of a metal, an insulator or a semiconductor. In FIG. 10, instead of a gas nozzle ring, a diffuser 18 made of a porous, fabric-like or sponge-like, preferably plasma-stable material is also arranged.

The media injector according to the invention can have different geometric configurations. In conjunction with a plasma source, but not restricted to this source, preferred geometric configurations are shown in FIGS. 11 and 12.

FIG. 11 shows a sectional view through a rotationally symmetric media injector with a gas feed line 1 on both sides. Distribution of gas by means of gas channel 1 occurs within gas nozzle 21. Gas can flow into the space between gas nozzle 21 and gas nozzle ring 13 through openings 2 for gas outlet. Gas can flow inward into processing chamber 8 via gas nozzle ring 13, which is preferably designed as an edge with an overflow.

Media injector MI with a rectangular configuration is shown in FIG. 12, in which equivalent components as in FIG. 11 are also provided.

In a preferred variant of the plasma source, the anode has a cylindrical shape and is arranged axially offset relative to a cathode, as is already known from the prior art. The medium can expediently be axially offset through the gap relative to the anode and be supplied to an area arranged on the side of the processing chamber opposite the cathode, or into an area arranged between the anode and cathode of the processing chamber. The medium can also be supplied axially offset relative to the anode in an area of the processing chamber arranged on the side of the cathode. It is also advantageous, if the medium is supplied through the gap in an area of the anode and/or cathode of the processing chamber. It is understood that the axial offset between the cathode and anode is not essential for function of the plasma source.

A spatial representation of a media injector MI preferred for a cylindrical plasma source is shown in FIG. 13. A gas feed line 1 is guided through an electrode 23 to a gas nozzle ring. The plasma source has a flat and/or sloped face, which is formed by an electrode 16. In modifications, the face can also follow a defined curve, for example, as in a Laval nozzle. The gas nozzle ring 13 is arranged beneath electrode 16, so that a gap space 7 is formed between the bottom of electrode 16 and the gas nozzle ring 13. The gas nozzle ring 13 sits on a work piece 18, which again sits on an electrode 17. It is understood that the components and materials described in conjunction with the variants of FIGS. 2 and 11 can also expediently be used in the variant of FIG. 13. A protective tube that is positioned in electrode 17 and protects it from contamination can also be provided. In order to keep forming contaminants on this protective tube and to prevent these contaminants from reaching the plasma again, this tube is very rough or knurled on the inside facing the plasma. The protective tube can be removed and cleaned.

The plasma source has additional components not shown in the drawing, especially an electron emitter, as well as optionally magnets for alignment and guiding of the plasma, and generates a plasma lobe that extends outside of the source. Positioning of the gap space 7 in the interior of the cylindrical electrode configuration 16, 17, 23 makes it possible to reduce or completely prevent direct evaporation of the gap limitation surfaces, for example, by atoms, molecules or clusters of the coating materials generated outside of the plasma source. Consequently, the parameters of the transport opening are unchanged for feed of gas, so that high operational stability can be achieved. The plasma lobe generated by the plasma source designed according to the invention is wider than with conventional plasma sources, as described, for example, in EP 0 463 203 A1 or EP 1 154 459 A2. A more homogeneous layer distribution on the substrates being coated can therefore be achieved. The increased homogeneity is particularly pronounced in areas with a large radial spacing from the axis of symmetry of the source. An ion current density, increased by about 25% relative to the mentioned apparatuses from the prior art, can also be achieved in the central area relative to the axis of symmetry of the source. The increase in ion current density in the peripheral area relative to the axis of symmetry of the source is about 50%.

A media injector according to the invention can advantageously be provided in a sputtering device for coating of substrates. Such a sputtering device has at least one gas inlet device for the sputtering and/or reactive gas and a sputtering cathode in a processing chamber, which includes at least one sputtering target with a sputtering surface. According to the invention, at least one gas inlet device is designed as a media injector according to the invention. During operation of the sputtering device, a plasma burns over the sputtering cathode and/or bombardment of the sputtering cathode with high-energy particles occurs. In the sectional view in FIG. 14, a gas nozzle 21 is arranged in the immediate vicinity of the sputtering cathode. Gas is guided into the gas nozzle 21 formed by tubular elements through a gas feed 1 and distributed via channel 11 through openings 2 or a gap space 7 for gas outlet.

The configuration depicted in FIG. 14 permits supply of gas in the immediate vicinity of the sputtering cathode 29. This supply of gas reduces the required amount of gas relative to a method, in which gas is admitted at another location into the processing chamber. Since the corresponding partial pressure of the gas at the location of the gas inlet is maximal, a relatively low pressure can also be used. Reactive gas is preferably admitted in the immediate vicinity of the sputtering cathode, if this reactive gas improves the sputtering process.

The sputtering device depicted in FIG. 14 also has a shielding element 31, which typically lies at least temporarily on a potential other than that of the sputtering cathode 29. Generally, a shielding lying at the potential of the installation ground is chosen. The gas feed occurs, in this case, in the Faraday dark space of the sputtering cathode, it being understood that the distances occurring in the gas nozzle 21 can be dimensioned correspondingly small.

For installation and/or adjustment and/or electrical insulation of the gas nozzle 21 relative to sputtering cathode 29 and shield 31, fastening elements 32 and 33 are provided. If different potentials are prescribed at least temporarily on the gas nozzle 21, sputtering cathode 29 and shield 31, these components are electrically insulated relative to each other. It can be ensured by appropriate shaping that the gas flows only in the direction of the plasma over the sputtering cathode 29.

Another variant of a sputtering device is shown in FIG. 15 with a gap space 7, formed between the sputtering cathode 29 and the gas nozzle 21 designed as a tubular element, and which permits gas feed directly adjacent to the sputtering cathode 29.

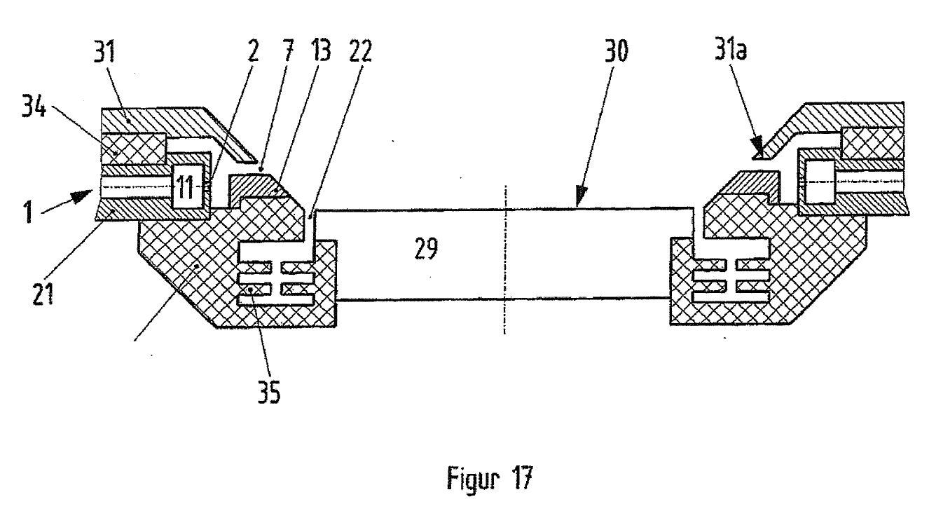

The sputtering device of the gas nozzle ring is shown in FIG. 16, which is formed from two components 13 and 14. The gas nozzle 21 and the gas nozzle rings 13 and 14 are designed self-centering. The gas nozzle ring 14 can made from an insulator and the gas nozzle ring 13 can lie at floating potential. In an alternative variant, the gas nozzle 21 is completely insulated from the other components.

The gas nozzle 21 and the gas nozzle rings 13 and 14 can also be designed similar to the shielding elements from DE-OS 2 149 606. The content of this document is fully incorporated in the present invention. In the intermediate shields 29, 22 described in DE-OS 2 149 606, a gas inlet device, designed as a media injector according to the invention, is integrated in the immediate vicinity of the sputtering cathode 29.

For assembly and/or adjustment and/or electrical insulation of the sputtering cathode 29 and gas nozzle 21, as well as gas nozzle rings 13 and 14, work pieces 32, 34 can also be provided, as shown in FIG. 16, which have protrusions 35 to form shaded zones. In other variants, it is also possible to integrate corresponding protrusions 35 in other components, like the gas nozzle 21. It is understood that their shaping and/or material must be adjusted accordingly. Material that reaches the area of gap 7 or 22 can be precipitated in the area of protrusion 35 as a layer. In this way, it is prevented that a conducting connection is produced between components, between which insulation is provided, from undesired deposited layers. The insulating work pieces 32 and 34 can also be designed as a work piece connected under component 21.

Another sputtering device with a media injector according to the invention is shown in FIG. 17 as a gas inlet device for a sputtering and/or reactive gas, in which the gap space 7 is allocated to an area above the sputtering surface 30 of the sputtering cathode 29. In this way, gas can be directly fed from the outside to the sputtering plasma in the space above the sputtering surface 30. The gap space 7 is preferably arranged peripherally. Feed of gas occurs through the gas feed line 1 into a gas nozzle 21, during which distribution occurs via a gas channel 11. Outlet of gas from the gas channel 11 then occurs through outlet openings 2. The gap space 7 is formed by the shielding element 31 on one side and by a gas nozzle ring 13 on the other. The shielding element 31 and/or gas nozzle ring 13 are designed as tubular elements according to the invention. The gap limitation surface is optionally formed by the face 31a of the shielding element 31.

The sputtering cathode 29 and gas nozzle ring 13 are preferably held in an electrically insulating work piece 32 in the depicted variant, which serves both for positioning of the gas nozzle 21 relative to gas nozzle ring 13 and for positioning of the gas nozzle 21 and gas nozzle ring 13 relative to sputtering cathode 29. Another electrically insulating work piece 34 is arranged between the shielding element 31 and gas nozzle 21, which permits positioning of the shielding element 31 relative to gas nozzle 21. The work piece 32 can have protrusions 35 to prevent continuous layers that could result in electrical short circuits. It is understood that the work piece 34 can be designed in the same manner as work piece 32 with protrusions 35.

Depending on the employed materials of the different components being joined to each other, the need for an electrically insulating function of work pieces 32 and/or 34 can drop out. This also applies, if adjacent components, like gas nozzle 21 and shielding element 31, lie at the same potential (for example, ground).

In a modification of the sputtering device according to the invention, several gas nozzles can be provided in the area of the sputtering cathode, in order to supply gas at different spacings from the sputtering surface or the substrate being coated. The particle density of the employed gas is expediently set high at the locations, at which this is required by the process. The circumstance that the sputtering effect is reduced by the formation of oxides on the surface of the sputtering target can also be taken into account, in which case oxides are applied to the substrate. In this case, it is advantageous to supply oxygen close to the substrate and sputtering gas close to the sputtering target.

### LIST OF REFERENCE NUMBERS

MI Media injector
1 Gas feed line
2 Outlet openings
3 Gas line
4 Gap
5 Gap limitation surface
6 Gap limitation surface
7 Gap space
8 Processing chamber
9 Tubular element
10 Tubular element
11 Gas channel
12 Gas channel, supply space
13 Gas nozzle ring
13a Face of gas nozzle ring
14 Workpiece
15 Work piece
16 Electrode
16a Face of electrode
17 Electrode
18 Work piece
19 Workpiece
20 Work piece
21 Gas nozzle
22 Gap
23 Electrode
24 Hole
25 Plasma shield
26 Cooling element/cold surface
27 Grid
28 Diffuser
29 Sputtering cathode
30 Sputtering surface
31 Shielding element
31a Face of shielding element
32 Fastening element
33 Fastening element
34 Fastening element
35 Protrusion

1. Media injector for transport of an especially fluid medium into a processing chamber with preferably a feed device and at least one gap as a transport opening for the medium, the gap having at least two gap limitation surfaces with a gap space arranged in between, characterized by the fact that at least one gap limitation surface is formed by at least one part of at least one face of a first tubular element.

2. Media injector according to claim 1, characterized by the fact that a second gap limitation surface opposite the first gap limitation surface is formed by at least part of a face of a second tubular element.

3. Media injector according to at least one of the preceding claims, characterized by the fact that a second gap limitation surface opposite the first gap limitation surface is formed by preferably a flat surface of a non-tubular work piece.

4. Media injector according to at least one of the preceding claims, characterized by the fact that several faces are provided to form a structured gap space.

5. Media injector according to at least one of the preceding claims, characterized by the fact that the gap has at least two gap segments.

6. Media injector according to at least one of the preceding claims, characterized by the fact that the tubular element has a cross-section with a closed periphery, preferably to form a continuous gap.

7. Media injector according to at least one of the preceding claims, characterized by the fact that the tubular element has a circular, oval, polygonal or rectangular cross section.

8. Media injector according to at least one of the preceding claims, characterized by the fact that the tubular element is turned from solid material or is a seamlessly welded or drawn tube.

9. Media injector according to at least one of the preceding claims, characterized by the fact that positioning of at least one component, element and/or work piece by shape-mated fastening is provided.

10. Media injector according to at least one of the preceding claims, characterized by the fact that the gap is formed between two spaced circular rings, stacked one above the other.

11. Media injector according to claim 10, characterized by the fact that the circular rings are designed one in the other for centering or self-centering.

12. Media injector according to at least one of the preceding claims, characterized by the fact that at least one supply space is arranged upstream of the gap to influence, especially increase, the uniformity of media flow, which is preferably connected to the processing chamber via hole-like and/or gap-like openings.

13. Media injector according to at least one of the preceding claims, characterized by the fact that protrusions to form shaded zones are provided in the gap space or space areas connected to it.

14. Media injector according to at least one of the preceding claims, characterized by the fact that at least one filling component is arranged in at least part of the gap space.

15. Media injector according to claim 14, characterized by the fact that at least one filling component has a supply space for transport of the medium into the gap space.

16. Media injector according to claim 14 or 15, characterized by the fact that at least one filling component is formed by at least one tubular element.

17. Media injector according to at least one of the preceding claims, characterized by the fact that at least one feed line is integrated in at least one of the tubular elements.

18. Media injector according to at least one of the preceding claims, characterized by the fact that at least one element, component or work piece is provided with an active and/or passive cooling element.

19. Media injector according to at least one of the preceding claims, characterized by the fact that a conductor, preferably a metal, especially steel, stainless steel, titanium, aluminum, copper, tantalum, tungsten, molybdenum, graphite, a semiconductor and/or an insulator, preferably ceramic or plastic, is provided as material for the components, elements or work pieces.

20. Media injector according to at least one of the preceding claims, characterized by the fact that at least parts of the surface of at least one element, component or work piece are coated with another material, especially with a protective coating material.

21. Media injector according to at least one of the preceding claims, characterized by the fact that the gap is part of an electrode arrangement.

22. Media injector according to at least one of the preceding claims, characterized by the fact that at least parts of the gap limitation surfaces lie at least temporarily at different electric potentials.

23. Media injector according to at least one of the preceding claims, characterized by the fact that the gap at least partially encloses the processing chamber.

24. Media injector according to at least one of the preceding claims, characterized by the fact that the media injector is provided for supply of the medium into a plasma chamber of a plasma device, in which a plasma can be ignited, preferably for coating of surfaces.

25. Media injector according to claim 24, characterized by the fact that the plasma can be generated by means of independent or non-independent gas discharge, with or without a magnetic field or by means of an electron or ion source.

26. Media injector according to claim 24 or 25, characterized by the fact that the gap is assigned to a Faraday dark space of the plasma.

27. Plasma and/or ion device with at least one media injector, characterized by the fact that the media injector is designed according to at least one of the claims 1 to 26.

28. Plasma and/or ion device according to claim 27, characterized by the fact that the device is designed as a plasma source with at least one cathode to generate electrons for ionization of a gas and at least an anode assigned to the cathode.

29. Plasma source according to claim 28, characterized by the fact that the cathode and anode are arranged within the processing chamber.

30. Plasma source according to one of the claims 28 or 29, characterized by the fact that the anode has a cylindrical shape and is arranged axially offset relative to the cathode.

31. Plasma source according to at least one of the claims 28 to 30, characterized by the fact that the medium can be fed through the gap into an area arranged axially offset to the anode and on a side of the processing chamber opposite the cathode.

32. Plasma source according to at least one of the claims 28 to 31, characterized by the fact that the medium can be fed through the gap into an area of the processing chamber arranged between the anode and cathode.

33. Plasma source according to at least one of the claims 28 to 32, characterized by the fact that the medium can be fed into an area of the processing chamber arranged on the side of the cathode and axially offset relative to the anode.

34. Plasma source according to at least one of the claims 28 to 33, characterized by the fact that the medium can be fed through the gap into an area of the anode and/or cathode.

35. Sputtering device for coating of substrates with at least one gas inlet device for a sputtering and/or reactive gas and a sputtering cathode, having at least one sputtering target with a sputtering surface, characterized by the fact that at least one gas inlet device is provided as media injector according to at least one of the claims 1 to 26.

36. Sputtering device according to claim 35, characterized by the fact that a gap of the media injector is arranged in the area above the sputtering surface.

37. Sputtering device according to claim 35 or 36, characterized by the fact that at least one gap limitation surface is formed as a shielding element or part of a shielding element.

38. Sputtering device according to at least one of the claims 35 to 37, characterized by the fact that the media injector has at least two, preferably axially and/or radially offset gaps to supply the same or different gases.
